(19) United States
(12) Patent Application Publication
(10) Pub. No.: US 2025/0212566 A1
(43) Pub. Date: Jun. 26, 2025

(54) DISPLAY DEVICE

(71) Applicant: LG Display Co., Ltd., Seoul (KR)

(72) Inventors: Soojin KIM, Paju-si (KR); Heumell BAEK, Paju-si (KR); SunHwa LEE, Paju-si (KR); Dae-Il KANG, Paju-si (KR)

(73) Assignee: LG Display Co., Ltd., Seoul (KR)

(21) Appl. No.: 18/762,210

(22) Filed: Jul. 2, 2024

(30) Foreign Application Priority Data
Dec. 21, 2023 (KR) 10-2023-0188381

(51) Int. Cl. H01L 33/50; H01L 25/075; H01L 33/46; H01L 33/58; H01L 33/62

(52) U.S. Cl. CPC H10H 20/8512; H01L 25/0753; H10H 20/841; H10H 20/855; H10H 20/857

(57) ABSTRACT

A display device in one example includes a substrate on which a plurality of sub-pixels are disposed, where each of the plurality of sub-pixels includes an emitting area and a non-emitting area adjacent to the emitting area. The display device further includes a plurality of light emitting diodes in the emitting area on the substrate, a planarization layer disposed on the light emitting diode and having an opening, and a plurality of optical layers disposed on the planarization layer. The planarization layer includes a central portion covering each of the plurality of light emitting diodes and an outer portion surrounding the central portion. Further, the central portion and the outer portion are spaced apart by the opening, and each of the plurality of optical layers covers the central portion of the planarization layer and fills an inside of the opening.

### CROSS-REFERENCE TO RELATED APPLICATIONS

This application claims priority to Korean Patent Application No. 10-2023-0188381 filed in the Republic of Korea on Dec. 21, 2023, the entire disclosure of which is hereby expressly incorporated by reference into the present application.

### BACKGROUND

### Field

The present disclosure relates to display device, and more particularly, to a display device using a light emitting diode, which can improve light efficiency and display performance.

### Discussion of the Related Art

A display device is widely used as a display screen of a notebook computer, a tablet computer, a smart phone, a portable display device, and a portable information device in addition to a display screen of a television or a monitor.

Among different types of display devices, a liquid crystal display device and an organic light emitting display device can display an image using a thin film transistor as a switching element. Since the liquid crystal display device is not a self-emitting method, the image is displayed using light irradiated from a backlight unit disposed under the liquid crystal display panel. Since such liquid crystal display device has the backlight unit, design can be limited, and the luminance and response speed can be deteriorated over time. On the other hand, since the organic light emitting display device includes an organic material, it can be vulnerable to moisture, and thus reliability and lifespan can be deteriorated over time.

In recent years, research and development of the light emitting diode display device using a micro light emitting diode are in the spotlight as a next-generation display because of its high quality and high reliability. In particular, research is being conducted to further improve the light efficiency of the light emitting diode display device.

### SUMMARY OF THE DISCLOSURE

The present disclosure has been made in view of the above problems and other limitations associated with the related art, and it is an object of the present disclosure to provide a display device with improved light efficiency.

In accordance with an aspect of the present disclosure, the above and other objects can be accomplished by the provision of a display device comprising a substrate on which a plurality of sub-pixels are disposed, the plurality of sub-pixels including an emitting area and a non-emitting area adjacent to the emitting area, a plurality of light emitting diodes in the emitting area on the substrate, a planarization layer disposed on the light emitting diode and having an opening, and a plurality of optical layers disposed on the planarization layer, wherein the planarization layer includes a central portion covering each of the plurality of light emitting diodes and an outer portion surrounding the central portion, the central portion and the outer portion are spaced apart by the opening, and each of the plurality of optical layers covers the central portion of the planarization layer and fills an inside of the opening.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a plan view of a display device according to an embodiment of the present invention.

FIGS. 2A and 2B are plan views of one pixel according to an embodiment of the present invention.

FIG. 3 is a cross-sectional view of a first sub-pixel of a display device according to a first embodiment of the present invention.

FIG. 4 is a cross-sectional view of a first sub-pixel of a display device according to a second embodiment of the present invention.

FIG. 5 is a cross-sectional view of a first sub-pixel of a display device according to a third embodiment of the present invention.

FIG. 6 is a cross-sectional view of a first sub-pixel of a display device according to a fourth embodiment of the present invention.

FIGS. 7A to 7G are diagrams illustrating a process of manufacturing a display device according to the second embodiment of the present invention.

FIG. 8 is a cross-sectional view of a pixel according to an example of the present invention.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be disposed between two other portions unless ‘just’ or ‘direct’ is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship. Further, the term “can” encompasses all the meanings and coverages of the term “may.”

Hereinafter, the embodiments of the present disclosure will be described in detail with reference to the accompanying drawings. All the components of each display device or apparatus according to all embodiments of the present disclosure are operatively coupled and configured.

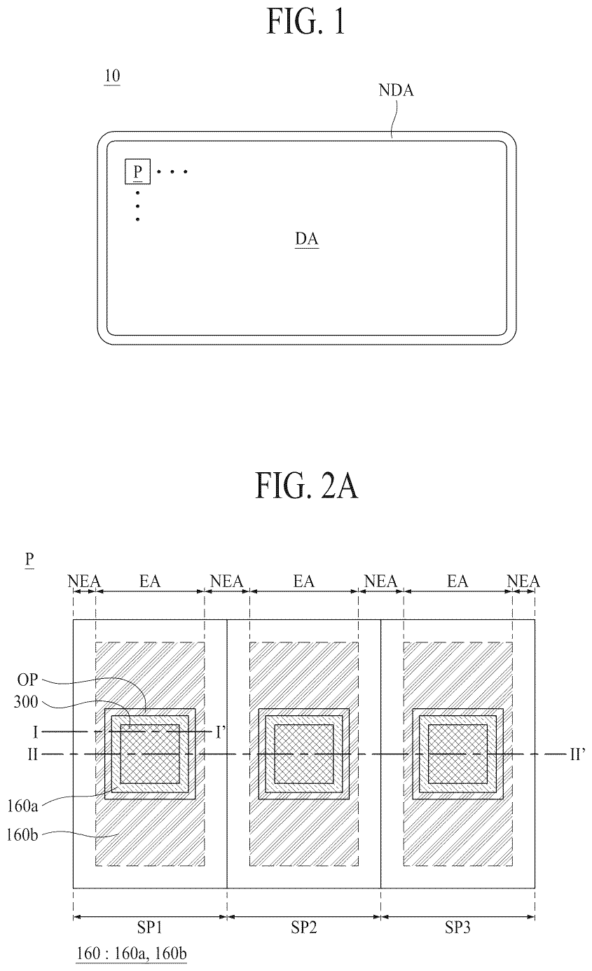

FIG. 1 is a plan view of a display device 10 according to an embodiment of the present invention.

Referring to FIG. 1, the display device 10 according to an embodiment of the present invention can include a display area DA and a non-display area NDA surrounding the display area DA. The non-display area NDA can surround the display area DA entirely or only in part. The display area DA is an area in which a screen (or image) can be displayed, and the non-display area NDA is an area in which a screen (or image) is not displayed.

The display area DA can include a plurality of pixels P. The plurality of pixels P can be arranged in a matrix form composed of a plurality of rows and columns. Further, the non-display area NDA can include a plurality of wirings, pads, driving circuits, and the like for driving the plurality of pixels P.

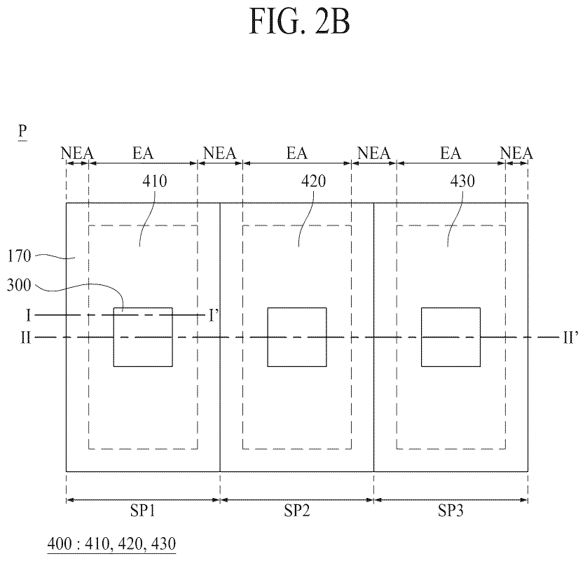

FIGS. 2A and 2B are plan views of one-pixel P according to an embodiment of the present invention. FIG. 2B shows a structure in which a bank 170 and an optical layer 400 are further formed in the structure of FIG. 2A. Each display device in all embodiments of the present disclosure can include pixels having the configurations shown in FIGS. 2A and 2B and/or any other configurations discussed in the present disclosure.

Referring to FIGS. 2A and 2B, each of the plurality of pixels P can include a first sub-pixel SP1, a second sub-pixel SP2, and a third sub-pixel SP3. The first sub-pixel SP1, the second sub-pixel SP2, and the third sub-pixel SP3 can emit different light from each other. For example, the first sub-pixel SP1 can emit red light, the second sub-pixel SP2 can emit green light, and the third sub-pixel SP3 can emit blue light, but is not limited thereto. Further, although FIGS. 2A and 2B illustrate that one-pixel P includes three sub-pixels SP1, SP2 and SP3, one-pixel P is not limited thereto, and one-pixel P can include a larger or different number of sub-pixels.

Each of the first sub-pixel SP1, the second sub-pixel SP2, and the third sub-pixel SP3 can include an emitting area EA and a non-emitting area NEA surrounding the emitting area EA. The non-emitting area NEA can surround the emitting area EA entirely or only in part. The emitting area EA is an area capable of emitting light, and the non-emitting area NEA is an area that does not emit light.

Referring to FIG. 2A, a light emitting diode 300 can be disposed in the emitting area EA of each of the first sub-pixel SP1, the second sub-pixel SP2, and the third sub-pixel SP3. The light emitting diode 300 can emit light.

A planarization layer 160 can be disposed in the light emitting area EA and the non-light emitting area NEA of each of the first sub-pixel, the second sub-pixel, and the third sub-pixel SP3, SP2, and SP3. The planarization layer 160 can be cover the light emitting diode 300. Further, the planarization layer 160 can include an opening OP surrounding the light emitting diode 300. The opening OP can have a ring shape having the light emitting diode 300 as a center. Further, an inside of the opening OP can be a central portion 160a of the planarization layer 160, and an outside of the opening OP can be an outer portion 160b of the planarization layer 160. For example, the central portion 160a and the outer portion 160b of the planarization layer 160 can be spaced apart from each other. Further, the central portion 160a of the planarization layer 160 can be disposed in the emitting area EA, and the outer portion 160b of the planarization layer 160 can be disposed in the emitting area EA and the non-emitting area NEA.

Referring to FIG. 2B, an optical layer 400 can be disposed in the light emitting area EA of each of the first sub-pixel SP1, the second sub-pixel SP2, and the third sub-pixel SP3. The optical layer 400 can be cover the light emitting diode 300, the central portion 160a of the planarization layer 160, and the opening OP. Further, the optical layer 400 can include a first optical layer 410 disposed in the first sub-pixel SP1, a second optical layer 420 disposed in the second sub-pixel SP2, and a third optical layer 430 disposed in the third sub-pixel SP3. The optical layer 400 can convert a color of light emitted from the light emitting diode 300, or can scatter the light emitted from the light emitting diode 300 and emit the light. A detailed description thereof will be provided later.

Further, a bank 170 can be disposed in the non-emitting area NEA of each of the first sub-pixel SP1, the second sub-pixel SP2, and the third sub-pixel SP3. The bank 170 can be disposed in a boundary area of each of the first sub-pixel, the second sub-pixel, and the third sub-pixel SP1, SP2, and SP3.

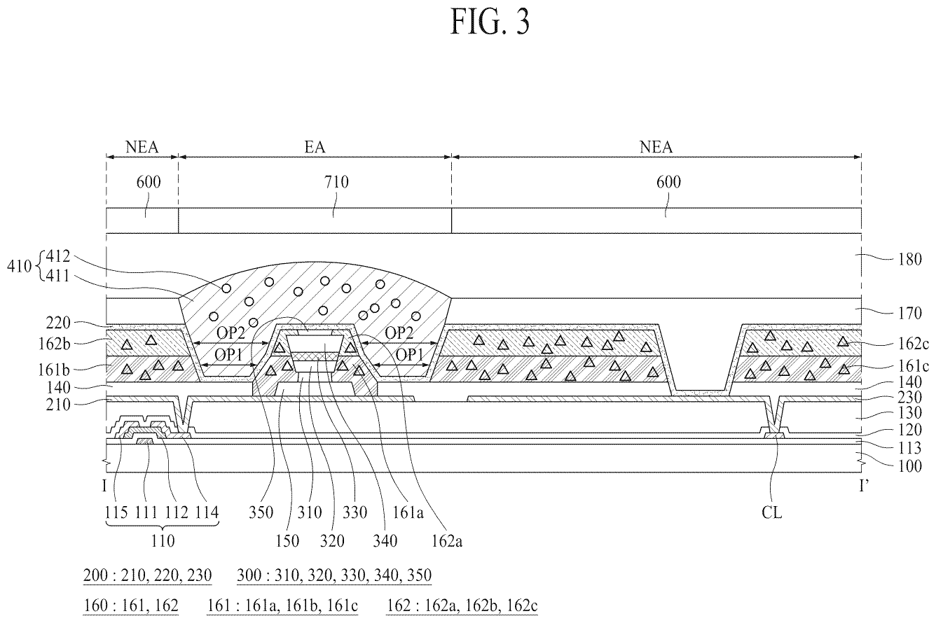

FIG. 3 is a cross-sectional view of the first sub-pixel SP1 of the display device according to a first embodiment of the present invention. Particularly, FIG. 3 is a cross-sectional view taken along line I-I′ of FIG. 2 according to the first embodiment.

Referring to FIG. 3, the first sub-pixel SP1 according to the first embodiment of the present invention can include a substrate 100, a thin film transistor 110, an interlayer insulating layer 120, a passivation layer 130, a lower insulating layer 140, an adhesive layer 150, a planarization layer 160, a bank 170, an encapsulation layer 180, a connection electrode 200, a light emitting diode 300, a first optical layer 410, a black matrix 600, a first color filter 710, and a common voltage line CL.

The substrate 100 can be made of glass or plastic, but is not limited thereto. The display device according to an embodiment of the present invention can be configured in a top emission method in which the emitted light is emitted upward. Therefore, as the material of the substrate 100, not only a transparent material but also an opaque material can be used.

The thin film transistor 110 can be disposed on the substrate 100. The thin film transistor 110 can include a gate electrode 111, a semiconductor layer 112, a gate insulating layer 113, a source electrode 114, and a drain electrode 115.

The gate electrode 111 of the thin film transistor 110 can be disposed on the substrate 100. Further, the semiconductor layer 112 can be disposed on the gate electrode 111. The semiconductor layer 112 can include a poly-silicon semiconductor or an oxide semiconductor. In addition, when the semiconductor layer 112 includes an oxide semiconductor, at least one oxide of indium-gallium-zinc-oxide (IGZO), indium-zinc-oxide (IZO), indium-gallium-tin-oxide (IGTO), and indium-gallium-oxide (IGO) can be included.

A gate insulating layer 113 can be disposed between the gate electrode 111 and the semiconductor layer 112 for insulating the gate electrode 111 from the semiconductor layer 112. The gate insulating layer 113 can consist of a single layer of silicon nitride (SiNx) or silicon oxide (SiOx) or multiple layers thereof. Further, although a bottom gate structure in which a semiconductor layer 112 is disposed on a gate electrode 111 is discussed, the present invention is not limited thereto. For example, the gate electrode 111 can disclose a top gate structure disposed on the semiconductor layer 112.

The source electrode 114 and the drain electrode 115 can be disposed on the semiconductor layer 112 while facing each other. Further, the common voltage line CL can be disposed on the gate insulating layer 113. The common voltage line CL can apply a common voltage. Further, the common voltage line CL can be formed of the same material as the source electrode 114 and the drain electrode 115, but is not limited thereto.

The interlayer insulating layer 120 can be disposed on the source electrode 114, the drain electrode 115, and the common voltage line CL. A contact hole exposing a portion of the source electrode 114 and the common voltage line CL can be formed in the interlayer insulating layer 120. Further, the interlayer insulating layer 120 can be formed of an inorganic insulating material, such as silicon oxide (SiOx), silicon nitride (SiNx), silicon oxynitride (SiOxNy).

The passivation layer 130 can be disposed on the thin film transistor 110. The passivation layer 130 can compensate for a step difference caused by the thin film transistor 110 to planarize an upper region of the thin film transistor 110. Further, the passivation layer 130 can be formed of an organic insulating material such as an acrylic resin, an epoxy resin, a phenolic resin, a polyamide resin, or a polyimide resin.

The first and third connection electrodes 210 and 230 are disposed on the passivation layer 130 and can be spaced apart from each other. The first connection electrode 210 can be electrically connected with the source electrode 114 of the thin film transistor 110 through a contact hole formed in the passivation layer 130. Further, the third connection electrode 230 can be electrically connected with the common voltage line CL through a contact hole formed in the passivation layer 130.

The first and third connection electrodes 210 and 230 can include a metal material such as Au, W, Pt, Si, Ir, Ag, Cu, Ni, Ti, or Cr, and an alloy thereof. Alternatively, the first and third connection electrodes 210 and 230 can include a transparent conductive material such as an indium tin oxide (ITO) or an indium zinc oxide (IZO).

The lower insulating layer 140 can be disposed on the first and third connection electrodes 210 and 230. The lower insulating layer 140 can expose a portion of the upper surface of each of the first and third connection electrodes 210 and 230.

The adhesive layer 150 is disposed in the emitting area EA and can fix the light emitting diode 300. The adhesive layer 150 can be disposed on the first connection electrode 210. For example, the adhesive layer 150 can be disposed on an upper surface of the first connection electrode 210 exposed by the lower insulating layer 140. Further, the adhesive layer 150 can be formed of a conductive material to electrically connect the first connection electrode 210 with the light emitting diode 300. For example, the adhesive layer 150 can be formed of a metal material such as indium, lead, or the like, but is not limited thereto.

The light emitting diode 300 can be disposed on the adhesive layer 150. The light emitting diode 300 can include a first electrode 310, a first semiconductor layer 320, an active layer 330, a second semiconductor layer 340, and a second electrode 350. Further, the light emitting diode 300 can have a vertical structure in which the first electrode 310, the first semiconductor layer 320, the active layer 330, the second semiconductor layer 340, and the second electrode 350 are sequentially stacked.

The first electrode 310 can be disposed on the adhesive layer 150. Since the adhesive layer 150 is made of the conductive material, the first electrode 310 can be electrically connected with the first connection electrode 210 through the adhesive layer 150. Accordingly, the first electrode 310 can be electrically connected with the source electrode 114 of the thin film transistor 110 through the first connection electrode 210.

The first semiconductor layer 320 can be disposed on the first electrode 310 to provide holes to the active layer 330. The first semiconductor layer 320 can be formed of a p-GaN-based semiconductor material such as GaN, AlGaN, InGaN, or AlInGaN. Further, Mg, Zn, Be or the like can be used as the impurity for doping the first semiconductor layer 320.

The active layer 330 can be disposed on the first semiconductor layer 320 and can be a light emitting layer that emits light. The active layer 330 can have a multi-quantum well (MQW) structure including a well layer and a barrier layer having a band gap higher than that of the well layer. For example, the active layer 330 can have a multi-quantum well structure such as InGaN/GaN, but is not limited thereto.

The second semiconductor layer 340 can be disposed on the active layer 330 to provide electrons to the active layer 330. The second semiconductor layer 340 can be formed of an n-GaN-based semiconductor material such as GaN, AlGaN, InGaN, or AlInGaN. Further, Si, Ge, Se, Te, C, or the like can be used as the impurity for doping the second semiconductor layer 340.

The second electrode 350 can be disposed on the second semiconductor layer 340 to be electrically connected with the common voltage line CL through the second connection electrode 220. Accordingly, the voltage applied to the source electrode 114 of the thin film transistor 110 can be transmitted to the first electrode 310 through the first connection electrode 210, and the voltage applied to the common voltage line CL can be transmitted to the second electrode 350 through the second connection electrode 220. For example, due to different voltage levels of the source electrode 114 of the thin film transistor 110 and the common voltage line CL, the light emitting diode 300 can emit light.

Each of the first and second electrodes 310 and 350 can include a metal material such as Au, W, Pt, Si, Ir, Ag, Cu, Ni, Ti, or Cr, and an alloy thereof. Alternatively, each of the first and second electrodes 310 and 350 can include a transparent conductive material such as an indium tin oxide (ITO) or an indium zinc oxide (IZO).

The planarization layer 160 can be disposed on the lower insulation layer 140 and can be disposed in the emitting area EA and the non-emitting area NEA. Further, the planarization layer 160 can have an opening OP and can include a first planarization layer 161 and a second planarization layer 162.

The first planarization layer 161 can be disposed on the lower insulation layer 140. Further, the first planarization layer 161 can include a central portion 161a disposed in the emitting area EA and an outer portion 161b disposed in the non-emitting area NEA.

The central portion 161a of the first planarization layer 161 can cover a side surface and a top surface of the adhesive layer 150 and can surround a side surface of the light emitting diode 300. Accordingly, the central portion 161a of the first planarization layer 161 can stably fix the light emitting diode 300 on the lower insulation layer 140 with the adhesive layer 150. The central portion 161a of the first planarization layer 161 surrounds the first electrode 310 of the light emitting diode 310, an entire side surface of the first semiconductor layer 320, and a portion of a side surface of the active layer 330, but is not limited thereto.

The outer portion 161b of the first planarization layer 161 can be surround the central portion 161a of the first planarization layer 161. In this case, the central portion 161a and the outer portion 161b of the first planarization layer 161 can be spaced apart from each other by a first opening OP1. The first opening OP1 can be disposed in the emitting area EA. Further, the first opening OP1 can be formed by removing a partial region of the first planarization layer 161 and can expose a portion of the lower insulation layer 140 to the outside. Further, the first opening OP1 can be disposed in a ring shape having the light emitting diode 300 as the center, but is not limited thereto. Further, the central portion 161a and the outer portion 161b of the first planarization layer 161 can be formed to have the same thickness.

The second planarization layer 162 can be disposed on the first planarization layer 161. Further, the second planarization layer 162 can include a central portion 162a disposed in the light emitting area EA and an outer portion 162b disposed in the non-light emitting area NEA.

The central portion 162a of the second planarization layer 162 can cover a side surface and a top surface of the light emitting diode 300 that are not covered by the central portion 161a of the first planarization layer 161. Since the central portion 161a of the first planarization layer 161 surrounds the first electrode 310, an entire side surface of the first semiconductor layer 320, and a portion of a side surface of the active layer 330, the central portion 162a of the second planarization layer 162 can surrounds a portion of the side surface of the active layer 330 and an entire side surface of the second semiconductor layer 340 and an entire side surface of the second electrode 350. Further, the central portion 162a of the second planarization layer 162 can cover a top surface of the light emitting diode 300, and compensate for a step difference caused by the light emitting diode 300 to planarize an upper region of the light emitting diode 300. In this case, a top surface of the second electrode 350 of the light emitting diode 300 can be exposed by the central portion 162a of the second planarization layer 162. Accordingly, the second electrode 350 of the light emitting diode 300 can be in contact with the second connection electrode 220.

The outer portion 162b of the second planarization layer 162 can surround the central portion 162a of the second planarization layer 162. In this case, the central portion 162a and the outer portion 162b of the second planarization layer 162 can be spaced apart from each other by a second opening OP2. The second opening OP2 can overlap the first opening OP1. Further, the second opening OP2 is formed by removing a partial region of the second planarization layer 162 and can expose a portion of the lower insulation layer 140 with the first opening OP1. Further, the central portion 162a and the outer portion 162b of the second planarization layer 162 can be formed to have the same thickness.

An angle formed by a side surface of the first planarization layer 161 exposed by the first opening OP1 and an upper surface of the lower insulation layer 140 can be an acute angle. Likewise, an angle formed by a side surface of the second planarization layer 162 exposed by the second opening OP2 and the upper surface of the lower insulation layer can be an acute angle. For example, each of the side surface of the first planarization layer exposed by the first opening OP1 and the side surface of the second planarization layer exposed by the second opening OP2 can have a tapered shape.

Each of the first and second planarization layers 161 and 162 can be formed of an inorganic insulating material or an organic insulating material. Further, each of the first and second planarization layers 161 and 162 can be formed to include different materials or can be formed to include the same material.

Each of the first and second planarization layers 161 and 162 can include scattering materials 161a and 162b. The scattering materials 161a and 162b can scatter light emitted from the light emitting diode 300, thereby changing a path of the light. Accordingly, light directed to the planarization layer 160 can be scattered, thereby blocking light leakage toward a side surface of the sub-pixel and improving light efficiency of the light emitting diode 300. The scattering materials 161a and 162b can include a metal oxide such as titanium oxide (TiO2), zirconium oxide (ZrO2), aluminum oxide (Al2O3), zinc oxide (ZnO2), silica (BaSO4), or tin oxide (SnO2). Alternatively, the scattering materials 161a and 162b can include an organic material such as polystyrene or polymethyl methacrylate (PMMA).

The second connection electrode 220 can be disposed on the lower insulation layer 140 and the planarization layer 160 and can be continuously disposed in the emitting area EA and the non-emitting area NEA. In this case, since the side surfaces of the first and second planarization layers 161 and 162 are formed in a tapered shape, the second connection electrode 220 can be disposed on a gentle slope. In particular, since the central portions 161a of the first planarization layers 161 and the central portions 162a of the second planarization layers 162 cover the light emitting diode 300, thereby compensating for a step difference in the side surface of the light emitting diode 300. Accordingly, the second connection electrode 220 can be formed on the gentle slope in the side surface of the light emitting diode 300. Further, since the central portions 161a of the first planarization layers 161 and the central portions 162a of the second planarization layers 162 compensate for a step difference in the upper surface of the light emitting diode 300, the second connection electrode 220 can be formed in the flat upper region of the light emitting diode 300. Accordingly, the second connection electrode 220 can be stably deposited.

The second connection electrode 220 can be electrically connected with the third connection electrode 230 through a contact hole formed in the planarization layer 160. Since the third connection electrode 230 receives the common voltage from the common voltage line CL, the second connection electrode 220 can also receive the common voltage. Further, the second connection electrode 220 can be in contact with and electrically connected with the second electrode 350 of the light emitting diode 300 on the planarization layer 160. Accordingly, the second electrode 350 can be electrically connected with the common voltage line CL through the second connection electrode 220. Accordingly, the voltage applied to the source electrode 114 of the thin film transistor 110 can be transmitted to the first electrode 310 through the first connection electrode 210, and the voltage applied to the common voltage line CL can be transmitted to the second electrode 350 through the second connection electrode 220. For example, due to different voltage levels of the source electrode 114 of the thin film transistor 110 and the common voltage line CL, the light emitting diode 300 can emit light.

The bank 170 can be disposed on the second connection electrode 220 and can be disposed in the non-emitting area NEA. The bank 170 can be made of an inorganic insulating material, and can include a material that absorbs light. Further, the bank 170 overlap the planarization layer 160 so that the thickness of the bank 150 can be minimized. Accordingly, light leakage between adjacent sub-pixels can be prevented while minimizing light absorption by the bank 170.

The first optical layer 410 can be disposed on the second connection electrode 220 and can be disposed in the emitting area EA. Further, the first optical layer 410 covers the light emitting diode 300 and can fill all of the inside of the first and second openings OP1 and OP2. For example, the first optical layer 410 can also be in contact with the second connection electrode 220 deposited on the side surface of the planarization layer 160 and a side surface of the bank 170.

The first optical layer 410 can include a first base layer 411 and a first wavelength conversion material 412 distributed inside the first base layer 411. The first base layer 411 can transmit light emitted from the light emitting diode 300. The first base layer 411 can include a transparent organic insulating material such as an acrylic resin, an epoxy resin, a phenolic resin, a polyamide resin, or a polyimide resin.

The first wavelength conversion material 412 can be a quantum dot. The quantum dot can absorb the light of a specific wavelength band, convert the absorbed light into light of a wavelength band different from the absorbed light, and emit the light. For example, the first wavelength conversion material 412 can absorb the blue light, convert the blue light into the red light, and emit the red light. Accordingly, the first wavelength conversion material 412 can convert the blue light incident from the light emitting diode 300 into the red light.

In this case, since the first optical layer 410 covers the upper surface and the side surface of the light emitting diode 300, the first optical layer 410 can convert all the light emitted from the upper surface and the side surface directions of the light emitting diode 300. In particular, since the first optical layer 410 fills the inside of the first and second openings OP1 and OP2, the first optical layer 410 can be disposed on the same layer as the active layer 330 of the light emitting diode 300. Accordingly, compared to a structure in which the wavelength conversion material is formed only on the upper portion of the light emitting diode, the light emitted from the side surface of the light emitting diode 300 can be more effectively converted, thereby improving light efficiency.

The encapsulation layer 180 can be disposed on the bank 170 and the first optical layer 410 and can be disposed in the emitting area EA and the non-emitting area NEA. The encapsulation layer 180 can compensate for a step difference due to the bank 170 and the first optical layer 410 to planarize upper regions of the bank 170 and the first optical layer 410.

The encapsulation layer 180 can transmit light converted from the first optical layer 410. The encapsulation layer 180 can include a transparent organic insulating material such as an acrylic resin, an epoxy resin, a phenolic resin, a polyamide resin, or a polyimide resin.

The black matrix 600 can be disposed on the encapsulation layer 180 and can be disposed in the non-emitting area NEA. The black matrix 600 can be formed of an inorganic insulating material and can include a material absorbing light.

The first color filter 710 can be disposed on the encapsulation layer 180 and can be disposed in the emitting area EA. Further, the first color filter 710 can be surrounded by the black matrix 600. The first color filter 710 can include a dye that transmits light of a specific wavelength band. For example, the first color filter 710 can transmit red light, block or absorb green and blue light. For example, the red light converted by the first optical layer 410 can transmit through the first color filter 710. Accordingly, the first sub-pixel SP1 can emit red light.

In conclusion, in the first embodiment of the present invention, by forming the opening OP in the planarization layer 160, the optical layer 410 including the wavelength conversion material 412 can be formed to cover the upper surface and the side surface of the light emitting diode 300. Accordingly, light efficiency of the light emitting diode 300 can be improved. Further, by disposing the scattering materials 161c and 162c inside the planarization layer 160, light directed toward the planarization layer 160 can be scattered. Accordingly, leakage of the light toward the side surface of the sub-pixel can be prevented, and thus light efficiency of the light emitting diode 300 can be further improved.

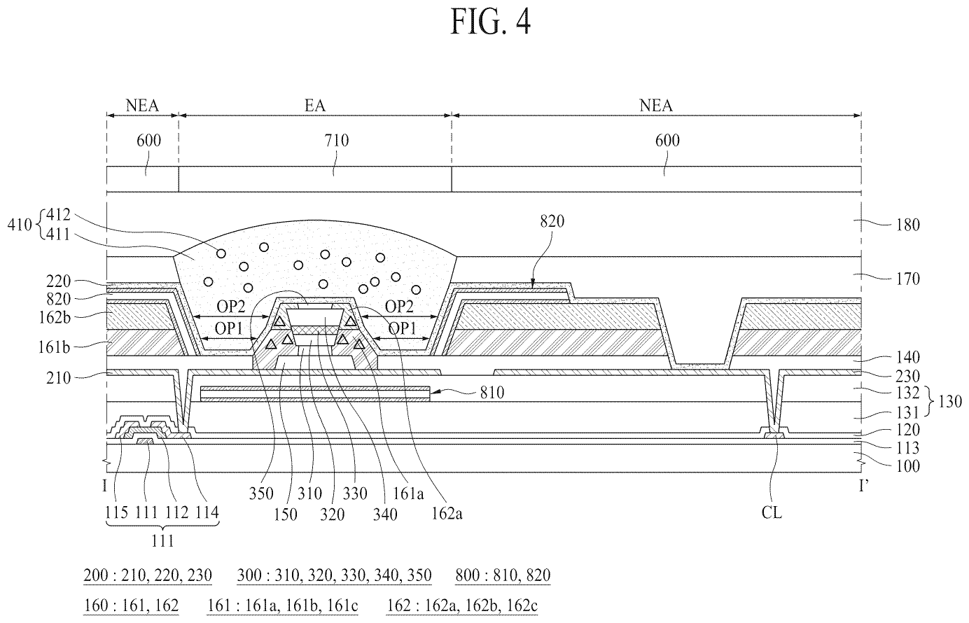

FIG. 4 is a cross-sectional view of the first sub-pixel SP1 according to a second embodiment of the present invention. Particularly, FIG. 4 is a cross-sectional view taken along line I-I′ of FIG. 2 according to the second embodiment. Compared to FIG. 3, FIG. 4 discloses substantially the same structure except for structures of the passivation layer 130, the planarization layer 160, and a reflection layer 800. Accordingly, the same reference numerals are used for components that are the same as those of the first sub-pixel SP1 shown in FIG. 3, and repeated descriptions are omitted or may be briefly provided.

As described above and with reference to FIGS. 3 and 4, the passivation layer 130 can be disposed on the thin film transistor 110. In this case, the passivation layer 130 can include a first passivation layer and a second passivation layer 131 and 132.

The first passivation layer 131 can be disposed on the thin film transistor 110. The first passivation layer 131 can compensate for a step difference caused by the thin film transistor 110 to planarize an upper region of the thin film transistor 110.

In this case, a lower reflective layer 810 can be further disposed on the first passivation layer 131. When the light generated by the light emitting diode 300 is emitted to face the substrate 100, the lower reflective layer 810 can reflect the light directed to the substrate 100 toward an upper portion of the substrate 100. Accordingly, the light extraction efficiency of the light emitting diode 300 can be improved. The lower reflective layer 810 can overlap the light emitting diode 300. Further, a width of the lower reflective layer 810 can be greater than that of the light emitting diode 300.

A second passivation layer 132 can be disposed on the lower reflective layer 810. The second passivation layer 132 can compensate for a step difference caused by the lower reflective layer 810 to planarize an upper region of the lower reflective layer 810.

The adhesive layer 150 can be disposed on the first connection electrode 210. For example, the adhesive layer 150 can be disposed on an upper surface of the first connection electrode 210 exposed by the lower insulating layer 140. Further, the adhesive layer 150 can be formed of a conductive material to electrically connect the first connection electrode 210 with the light emitting diode 300. For example, the adhesive layer 150 can be formed of a metal material such as indium, lead, or the like, but is not limited thereto. In this case, referring to FIG. 4, unlike the first embodiment disclosed in FIG. 3, the planarization layer 160 may not include the scattering material.

The planarization layer 160 can include the first and second planarization layers 161 and 162. The first planarization layer 161 can include the central portion 161a disposed in the emitting area EA and the outer portion 161b disposed in the non-emitting area NEA. Further, the second planarization layer 162 can include the central portion 162a disposed in the emitting area EA and the outer portion 162b disposed in the non-emitting area NEA.

In this case, a side surface reflective layer 820 can be further disposed on the outer portions 161b of the first planarization layers 161 and the outer portions 162b of the second planarization layers 162. The side surface reflective layer 820 can be covers a side surface of the outer portion 161b of the first planarization layer 161. Further, the side surface reflective layer 820 can be covers a top surface and a side surface of the outer portion 162b of the second planarization layer 162.

When the light generated by the light emitting diode 300 is emitted to face the side surface of the sub-pixel SP, the side surface reflective layer 820 can reflect the light directed to the outer portions 161b of the first planarization layers 161 and the outer portions 162b of the second planarization layers 162 toward an upper portion of the substrate 100. Accordingly, the light extraction efficiency of the light emitting diode 300 can be improved. The side surface reflective layer 820 can be disposed to face the side surface of the light emitting diode 300. In particular, the side surface reflective layer 820 can face the side surface of the active layer 330 of the light emitting diode 300.

Each of the lower reflective layer 810 and the side surface reflective layer 820 can include a metal material such as Au, W, Pt, Si, Ir, Ag, Cu, Ni, Ti, or Cr, and an alloy thereof. Alternatively, each of the lower reflective layer 810 and the side surface reflective layer 820 can include a transparent conductive material such as an indium tin oxide (ITO) or an indium zinc oxide (IZO). Further, each of the lower reflective layer 810 and the side surface reflective layer 820 can be formed as a single layer or multiple layers. For example, each of the lower reflective layer 810 and the side surface reflective layer 820 can be formed in a triple layer in which the transparent conductive material, the metal material, and the transparent conductive material are sequentially stacked.

The second connection electrode 220 is disposed on the lower insulation layer 140, the planarization layer 160, and the side surface reflection layer 820 and can be continuously disposed in the emitting area EA and the non-emitting area NEA. In this case, since the side surfaces of the first and second planarization layers 161 and 162 are formed in a tapered shape, the side surface reflection layer 820 can maintain the tapered shape even if the side surface reflection layer 820 is deposited on the side surfaces of the first and second planarization layers 161 and 162. Accordingly, since the second connection electrode 220 is formed on a gentle slope, it can be stably deposited.

In conclusion, the second embodiment of the present invention discloses the additional formation of the reflective layer 800 including the lower reflective layer 810 and the side surface reflective layer 820. Specifically, the lower reflective layer 810 is disposed below the light emitting diode 300 and can reflect light emitted directed to the substrate 100 toward the upper side of the substrate 100. In addition, the side surface reflective layer 820 can reflect light directed to the side surface of the sub-pixel SP toward the upper side of the substrate 100. Accordingly, light efficiency of the light emitting diode 300 can be improved.

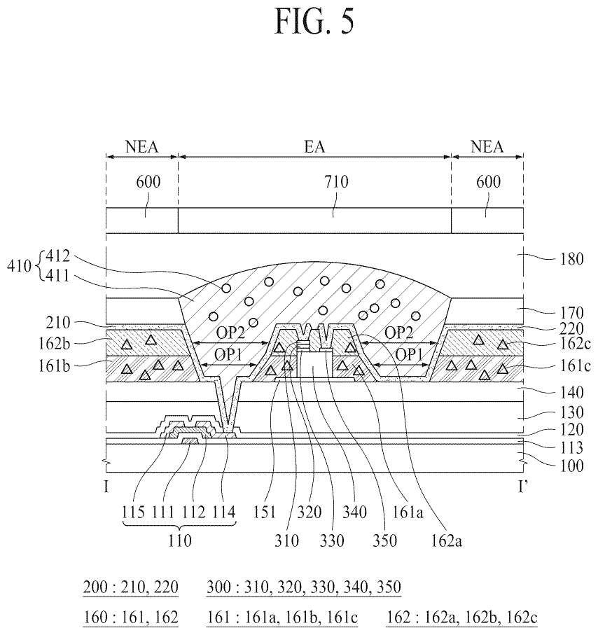

FIG. 5 is a cross-sectional view of the first sub-pixel SP1 according to a third embodiment of the present invention. Particularly, FIG. 5 is a cross-sectional view taken along line I-I′ of FIG. 2 according to the third embodiment. Compared with FIG. 3, FIG. 5 discloses substantially the same structure except for the structure of the light emitting diode 300. Accordingly, the same reference numerals are used for components that are the same as those of the first sub-pixel SP1 shown in FIG. 3, and repeated descriptions are omitted or may be briefly provided.

As described above in FIG. 3, the light emitting diode 300 can be disposed on the adhesive layer 151. In this case, the adhesive layer 151 fixes the light emitting diode 300 and can be formed of a cured material or a photo-cured material, but is not limited thereto. Further, the light emitting diode 300 disclosed in FIG. 3 and the light emitting diode 300 disclosed in FIG. 5 have different stacked structures. For example, the light emitting diode 300 disclosed in FIG. 3 can have a vertical structure, and the light emitting diode 300 disclosed in FIG. 5 can have a horizontal structure. Further, since the function of each component of the light emitting diode 300 disclosed in FIG. 5 is the same as the function of each component of the light emitting diode 300 disclosed in FIG. 3, a description thereof will be omitted or may be briefly provided.

Referring to FIG. 5, the light emitting diode 300 can include a first electrode 310, a first semiconductor layer 320, an active layer 330, a second semiconductor layer 340, and a second electrode 350.

The second semiconductor layer 340 can be disposed on the adhesive layer 151 to provide electrons to the active layer 330. Further, the active layer 330 can be disposed on the second semiconductor layer 340 and can be a light emitting layer emitting light. The first semiconductor layer 320 can be disposed on the active layer 330 to provide holes to the active layer 330.

As described above, the light emitting diode 300 can be manufactured by sequentially stacking the second semiconductor layer 340, the active layer 330, and the first semiconductor layer 320, and then etching a predetermined portion to form the first electrode 310 and the second electrode 350. In this case, the etched region is a region for separating the first electrode 310 and the second electrode 350, and a predetermined portion can be etched to expose a portion of the second semiconductor layer 340. For example, the active layer 330, the first semiconductor layer 320, and the first electrode 310 can be stacked on one side of the upper surface of the second semiconductor layer 340 and the second electrode 350 can be stacked on the other side of the upper surface of the second semiconductor layer 340. Accordingly, the first electrode 310 and the second electrode 350 can be formed at different heights.

The first electrode 310 is disposed on the first semiconductor layer 320 and can be electrically connected with the source electrode 114 of the thin film transistor 110 through the first connection electrode 210. Further, the second electrode 350 can be disposed on the exposed second semiconductor layer 340 and can be electrically connected with the common voltage line CL through the second connection electrode 220. Accordingly, the voltage applied to the source electrode 114 of the thin film transistor 110 can be transmitted to the first electrode 310 through the first connection electrode 210, and the voltage applied to the common voltage line CL can be transmitted to the second electrode 350 through the second connection electrode 220. For example, due to different voltage levels of the source electrode 114 of the thin film transistor 110 and the common voltage line CL, the light emitting diode 300 can emit light.

In this case, upper surfaces of the first and second electrodes 310 and 350 can be exposed by the central portion 162a of the second planarization layer 162. Accordingly, the first electrode 310 can be in contact with the first connection electrode 210, and the second electrode 320 can be in contact with the second connection electrode 220. Further, the passivation layer 130 and the lower insulation layer 140 are disposed on the thin film transistor 110, and the first connection electrode 210 can be in contact with the source electrode 114 of the thin film transistor 110 through a contact hole formed in the passivation layer 130 and the lower insulation layer 140.

Thus, as in the first embodiment, the third embodiment can form the opening OP in the planarization layer 160, such that the optical layer 410 including the wavelength conversion material 412 covers the upper surface and the side surface of the light emitting diode 300. Thus, light efficiency of the light emitting diode 300 can be improved. Further, by disposing the scattering materials 161c and 162c inside the planarization layer 160, light directed to the planarization layer 160 can be scattered. Thus, leakage of light directed to the side surface of the sub-pixel can be prevented, and thus light efficiency of the light emitting diode 300 can be further improved.

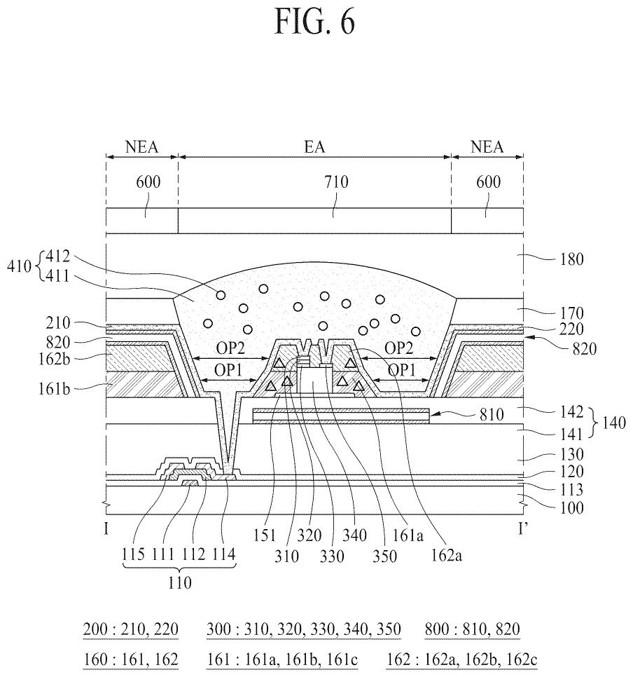

FIG. 6 is a cross-sectional view of the first sub-pixel SP1 according to a fourth embodiment of the present invention. Particularly, FIG. 6 is a cross-sectional view taken along line I-I′ of FIG. 2 according to the fourth embodiment. Compared with FIG. 5, FIG. 6 discloses substantially the same structure except for structures of the lower insulating layer 140, the planarization layer 160, and the reflection layer 800. Accordingly, the same reference numerals are used for components that are the same as those of the first sub-pixel SP1 shown in FIG. 5, and repeated descriptions are omitted or may be briefly provided.

As described above and referring to FIGS. FIGS. 5 and 6, the lower insulation layer 140 can be disposed on the passivation layer 130. In this case, the lower insulation layer 140 can include a first lower insulation layer 141 and a second lower insulation layer 142. Further, as described in FIG. 4, the first sub-pixel SP1 can further include the reflective layer 800, and the reflective layer 800 can include the lower reflective layer 810 and the side surface reflective layer 820.

The first lower insulating layer 141 can be disposed on the first connection electrode 210. The first lower insulating layer 141 can compensate for a step difference caused by the first connection electrode 210 to planarize an upper region of the first connection electrode 210.

The lower reflective layer 810 can be disposed on the first lower insulation layer 141. Further, the second lower insulation layer 142 can be disposed on the lower reflective layer 810. The second lower insulation layer 142 can compensate for a step difference caused by the lower reflective layer 810 to planarize an upper region of the lower reflective layer 810.

Therefore, like the second embodiment of the present invention, the fourth embodiment discloses additional formation of the reflective layer 800 including the lower reflective layer 810 and the side surface reflective layer 820. Specifically, the lower reflective layer 810 can be disposed below the light emitting diode 300 and can reflect light directed to the substrate 100 toward the upper side of the substrate 100. Further, the side surface reflective layer 820 can reflect light directed to the side surface of the sub-pixel SP toward the upper side of the substrate 100. Accordingly, light efficiency of the light emitting diode 300 can be improved.

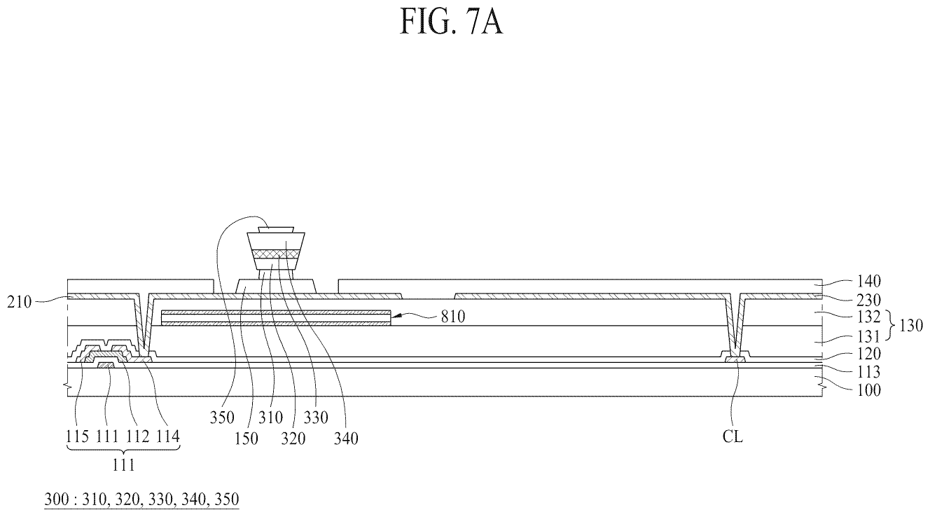

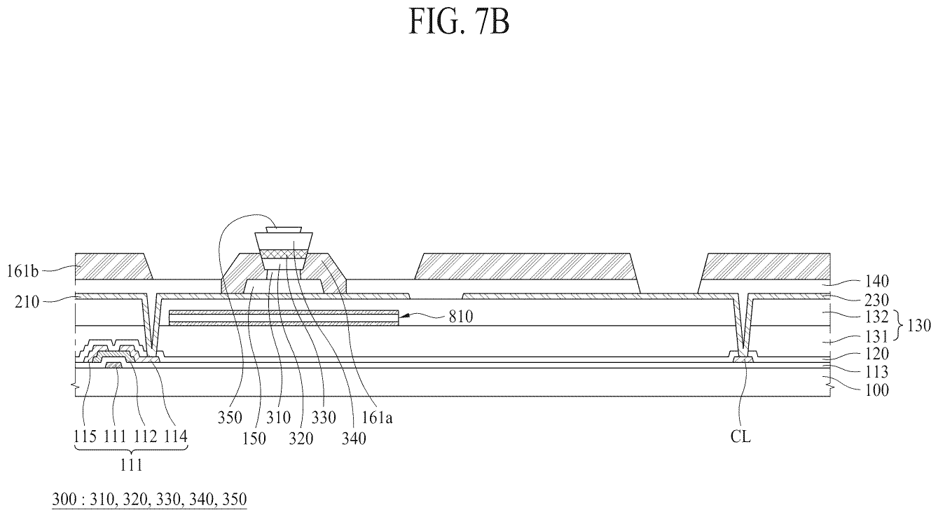

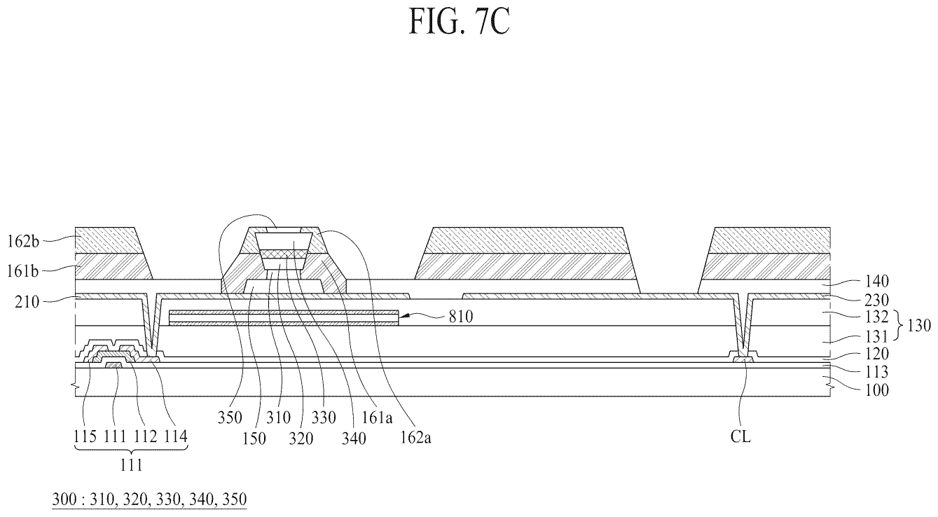

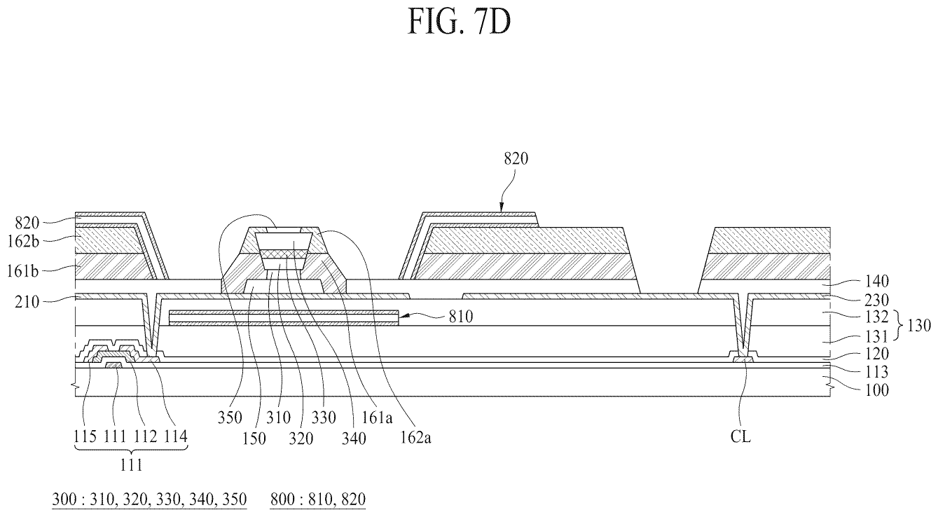

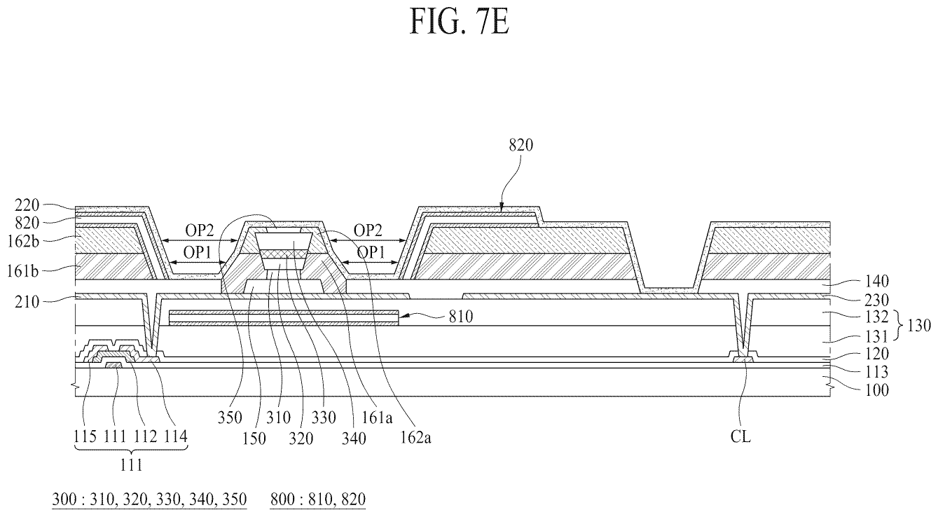

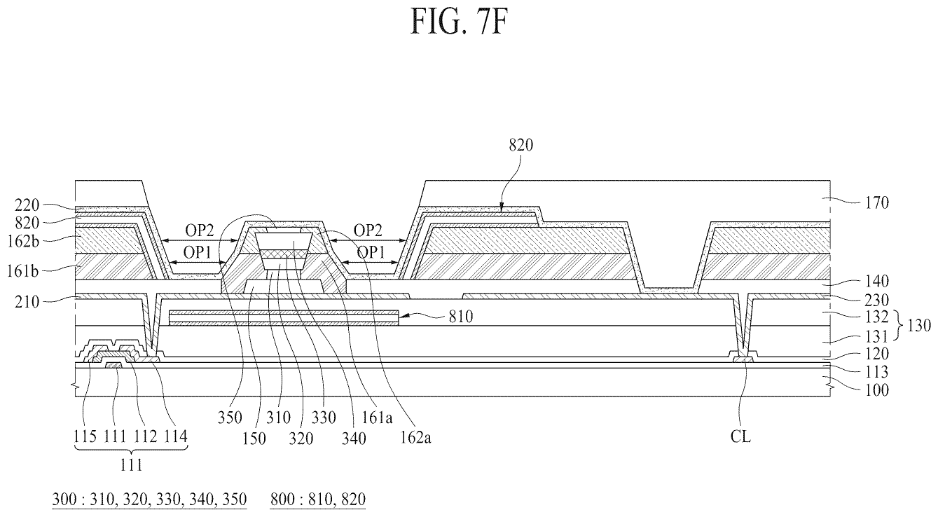

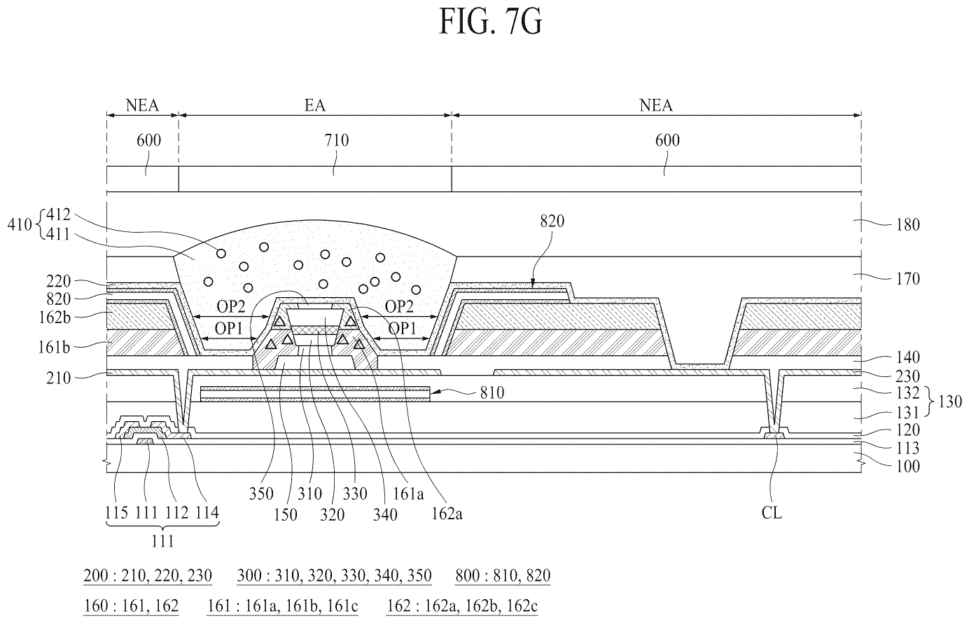

FIGS. 7A to 7G are diagrams illustrating a process of manufacturing a display device according to the second embodiment of the present invention. Particularly, FIGS. 7A to 7G illustrate a process of manufacturing the first sub-pixel SP1 of the display device.

Referring to FIG. 7A, a thin film transistor 110, a common voltage line CL, an interlayer insulating layer 120, a first passivation layer 131, a lower reflection layer 810, a second passivation layer 132, a first connection electrode 210, a third connection electrode 230, a lower insulation layer 140, an adhesive layer 150, and a light emitting diode 300 can be sequentially formed on a substrate 100.

The lower reflective layer 810, the adhesive layer 150, and the light emitting diode 300 can be formed in the center of the light emitting area EA. Further, the lower reflective layer 810, the adhesive layer 150, and the light emitting diode 300 can be formed to overlap each other.

The adhesive layer 150 fixes the light emitting diode 300 on the first connection electrode 210 and can electrically connect the light emitting diode 300 with the first connection electrode 210.

Referring to FIG. 7B, a first planarization layer 160 can be formed on the lower insulation layer 140. After a planarization material is deposited on an entire surface of the substrate 100, a partial region of the deposited planarization material can be removed to form a first opening OP1. By the first opening OP1, the first planarization layer 161 can include a central portion 161a and an outer portion 161b surrounding the central portion 161a. For example, the removed region can become the first opening OP1, and the remaining planarization material can be the first planarization layer 161. In this case, since the central portion 161a of the first planarization layer 161 covers a side surface and a top surface of the adhesive layer 150 and surrounds a side surface of the light emitting diode 300, the light emitting diode 300 can be stably fixed on the second lower insulation layer 142.

Referring to FIG. 7C, a second planarization layer 162 can be formed on the first planarization layer 161. After a planarization material is deposited on the entire surface of the substrate 100, a partial region of the deposited planarization material can be removed to form a second opening OP2. The second opening OP2 can overlap the first opening OP1. By the second opening OP2, the second planarization layer 162 can include a central portion 162a and an outer portion 162b surrounding the central portion 162a. For example, the removed region can become the second opening OP2, and the remaining planarization material can become the second planarization layer 162. Since the central portion 162a of the second planarization layer 161 covers the upper surface and the side surface of the light emitting diode 300, the upper portion and the side surface region of the light emitting diode 300 can be flattened by compensating for the step difference caused by the light emitting diode 300. In this case, an upper surface of the second electrode 350 of the light emitting diode 300 can be exposed by the central portion 162a of the second planarization layer 162.

Referring to FIG. 7D, a side surface reflective layer 820 can be formed on the second planarization layer 162. After depositing a metal material or a transparent conductive material on the entire surface of the substrate 100, a partial region of the deposited metal material or the deposited transparent conductive material can be removed to form the side surface reflective layer 820. Specifically, a region overlapping the light emitting diode 300 and the opening OP can be removed from the metal material or the transparent conductive material deposited on the entire surface of the substrate 100. For example, the side surface reflective layer 820 can be formed to cover a side surface of the outer portion 161b of the first planarization layer 161 and a top surface and a side surface of the outer portion 162b of the second planarization layer 162. When the side surface reflective layer 820 includes multiple layers, the side surface reflective layer 820 can be formed by sequentially depositing a plurality of materials on the entire surface of the substrate 100, and then removing a partial region of deposited the plurality of materials. For example, after depositing the transparent conductive material, the metal material, and the transparent conductive material on the entire surface of the substrate 100, a partial region of the materials can be removed to form the side surface reflective layer 820 including a triple layer.

Referring to FIG. 7E, a second connection electrode 220 can be formed on the entire surface of the substrate 100. For example, the second connection electrode 220 can be formed on the lower insulation layer 140, the planarization layer 160, and the side surface reflection layer 820. In this case, the side surface of the light emitting diode 300 has the gentle slope by the central portions 161a of the first planarization layer 161 and the central portions 162a of the second planarization layer 162, so that the second connection electrode 220 can be stably deposited on the side surface of the light emitting diode 300. Further, since the upper region of the light emitting diode 300 is planarized by the central portions 161a of the first planarization layer 161 and the central portions 162a of the second planarization layer 162, the second connection electrode 220 can be stably deposited on the upper area of the light emitting diode 300. Further, since the side surface reflection layer 820 deposited on the side surfaces of the first planarization layer 161 and second planarization layer 162 has the tapered shape, the second connection electrode 220 can be stably deposited on the side surface reflection layer 820. Accordingly, the second connection electrode 220 can be stably deposited on the entire surface of the substrate 100 and can be in contact with the second electrode 350 of the light emitting diode 300.

Referring to FIG. 7F, a bank 170 can be formed on the second connection electrode 220. After depositing an inorganic insulating material on the entire surface of the substrate 100, the bank 170 can be formed by removing a partial area of the deposited inorganic insulating material. Further, the bank 170 has hydrophobicity and can include black particles. Specifically, an area overlapping the emitting area EA can be removed from the inorganic insulating material deposited on the entire surface of the substrate 100. For example, the bank 170 can be formed on the planarization layer 160 and the second connection electrode 220 in the non-emitting area NEA.

Referring to FIG. 7G, a first optical layer 410, an encapsulation layer 180, a black matrix 600, and a first color filter 710 can be sequentially formed on a substrate 100.

The first optical layer 410 can include a first base layer 411 and a first wavelength conversion material 412 distributed inside the first base layer 411. As described above, the first base layer 411 includes a transparent organic insulating material, and the first wavelength conversion material 412 can be a quantum dot. Further, the first optical layer 410 can completely cover the top and side surfaces of the light emitting diode 300 and fill the inside of the first and second openings OP1 and OP2. Further, the first optical layer 410 can be formed through an inkjet process.

The encapsulation layer 180 can be formed on the entire surface of the substrate 100 and can be disposed in the emitting area EA and the non-emitting area NEA. The black matrix 600 and the first color filter 710 can be formed on the encapsulation layer 180. The black matrix 600 can be disposed in the non-emitting area NEA, and the first color filter 710 can be disposed in the emitting area EA.

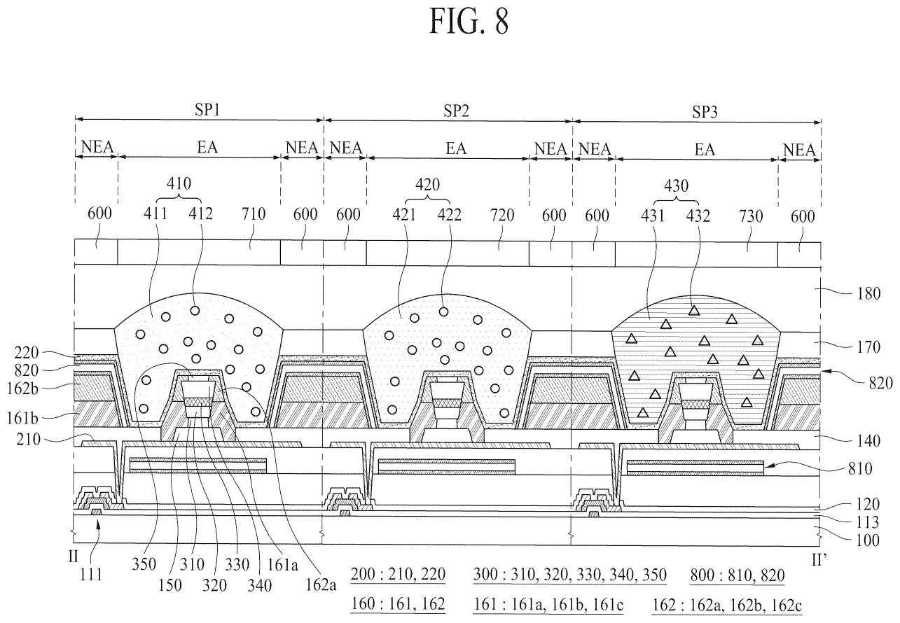

FIG. 8 is a cross-sectional view of a pixel P of a display device according to an embodiment of the present invention. Particularly, FIG. 8 is a cross-sectional view taken along line II-II′ in FIG. 2 according to this embodiment.

Referring to FIG. 8, one-pixel SP according to an embodiment of the present invention can include a first sub-pixel SP1, a second sub-pixel SP2, and a third sub-pixel SP3. Since the first sub-pixel SP1 has the same structure as that of the second embodiment disclosed in FIG. 4, the same reference numerals are used, and repeated descriptions are omitted. In addition, the second and third sub-pixels SP2 and SP3 have substantially the same structure as the first sub-pixel SP1, except for the configuration of the optical layer 400 and the color filter 700. Accordingly, the same reference numerals are used for the components that are the same as those of the first sub-pixel SP1, and repeated descriptions are omitted.

As described above and referring to FIGS. 4 and 8, the first sub-pixel SP1 can include the first optical layer 410. Further, the first optical layer 410 can include the first base layer 411 and the first wavelength conversion material 412 distributed inside the first base layer 411. The first base layer 411 can include the transparent organic insulating material, and the first wavelength conversion material 412 can be the quantum dot.

The first wavelength conversion material 412 can absorb the blue light, convert the blue light into the red light, and emit the red light. Accordingly, the first wavelength conversion material 412 can convert the blue light incident from the light emitting diode 300 into the red light.

Further, the first sub-pixel SP1 can include the first color filter 710. The first color filter 710 can transmit red light, block or absorb green and blue light. For example, the red light converted by the first optical layer 410 can transmit the first color filter 710. Accordingly, the first sub-pixel SP can emit red light.

The second sub-pixel SP2 can include a second optical layer 420. Further, the second optical layer 420 can include a second base layer 421 and a second wavelength conversion material 422 distributed inside the second base layer 421. The second base layer 421 can be formed of the same material as the first base layer 411. Further, the second wavelength conversion material 422 can be the quantum dot. The diameter of the quantum dot of the second wavelength conversion material 422 can be different from the diameter of the quantum dot of the first wavelength conversion material 412.

The second wavelength conversion material 422 can absorb blue light, convert the blue light into green light, and emit the green light. Accordingly, the second wavelength conversion material 422 can convert the blue light incident from the light emitting diode 300 into green light.

Further, the second sub-pixel SP2 can include a second color filter 720. The second color filter 720 can transmit green light and block or absorb red and blue light. For example, the green light converted by the second optical layer 420 can transmit through the second color filter 720. Accordingly, the second sub-pixel SP2 can emit green light.

The third sub-pixel SP3 can include a third optical layer 430. Further, the third optical layer 430 can include a third base layer 431 and a scattering material 433 distributed inside the third base layer 431. The third base layer 431 can be formed of the same material as those of the first and second base layers 411 and 421.

When the third sub-pixel SP3 is a blue sub-pixel, the third sub-pixel SP3 can include the scattering material 433 instead of the wavelength conversion material. Specifically, since the light emitting diode 300 emits blue light, the third sub-pixel SP3 may not convert wavelengths of light emitted from the light emitting diode 300. Accordingly, the third sub-pixel SP3 may not include the wavelength conversion material.

The scattering material 433 scatters light emitted from the light emitting diode 300, thereby changing a path of the light. Accordingly, light efficiency of the third sub-pixel SP3 can be improved. The scattering material 433 can include a metal oxide such as titanium oxide (TiO2), zirconium oxide (ZrO2), aluminum oxide (Al2O3), indium oxide (In2O3), silica, zinc oxide (ZnO2), barium sulfate (BaSO4), or tin oxide (SnO2). Alternatively, the scattering materials 433 can include an organic material such as polystyrene or polymethyl methacrylate (PMMA).

Further, the third sub-pixel SP3 can include a third color filter 730. The third color filter 730 can transmit blue light, block or absorb red and green light. For example, blue light scattered by the third optical layer 430 can transmit through the third color filter 730. Accordingly, the third sub-pixel SP3 can emit blue light.

In conclusion, in the first sub-pixel SP1, the second sub-pixel SP2, and the third sub-pixel SP3, each of the first to third optical layers 410 to 430 including the wavelength conversion material 412 and 422 or the scattering material 432 can cover the top surface and the side surface of the light emitting diode 300. Accordingly, light efficiency of the light emitting diode 300 can be improved in each sub-pixel SP.

According to one or more aspects of the present disclosure, the following advantageous effects can be obtained by the presently embodied inventions.

According to the present disclosure, the plurality of light conversion layers can be formed so that light efficiency can be improved, and reflectance due to external light can be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate on which a plurality of sub-pixels are disposed, each of the plurality of sub-pixels including an emitting area and a non-emitting area adjacent to the emitting area;
a plurality of light emitting diodes disposed in the emitting area on the substrate;
a planarization layer disposed on the light emitting diode, the planarization layer having an opening; and
a plurality of optical layers disposed on the planarization layer,
wherein the planarization layer includes a central portion covering each of the plurality of light emitting diodes and an outer portion surrounding the central portion,
the central portion and the outer portion are spaced apart by the opening of the planarization layer, and
each of the plurality of optical layers covers the central portion of the planarization layer and fills an inside of the opening of the planarization layer.

2. The display device of claim 1, wherein side surfaces of the central portion and the outer portion of the planarization layer are tapered.

3. The display device of claim 1, wherein the planarization layer includes a first planarization layer disposed on the substrate and a second planarization layer disposed on the first planarization layer,
the first planarization layer includes a first central portion covering a side surface of the light emitting diode and a first outer portion surrounding the first central portion, and
the second planarization layer includes a second central portion covering an upper surface of the light emitting diode and a second outer portion surrounding the second central portion.

4. The display device of claim 3, wherein the opening of the planarization layer includes a first opening and a second opening overlapping the first opening,
the first central portion and the first outer portion are spaced apart by the first opening, and
the second central portion and the second outer portion are spaced apart by the second opening.

5. The display device of claim 3, wherein each of the first planarization layer and the second first planarization layer includes a scattering material.

6. The display device of claim 3, wherein each of the plurality of sub-pixels includes a reflective layer, and
the reflective layer includes a lower reflective layer disposed below the light emitting diode and a side surface reflective layer disposed on the first planarization layer and the second planarization layer.

7. The display device of claim 6, wherein the lower reflective layer overlaps the light emitting diode.

8. The display device of claim 6, wherein the side surface reflective layer faces a side surface of the light emitting diode, and is disposed on a side surface of the outer portion of the planarization layer.

9. The display device of claim 1, wherein the plurality of sub-pixels include a first sub-pixel configured to emit red light,
the plurality of optical layers include a first optical layer disposed in the first sub-pixel, and
the first optical layer includes a first base layer and a first wavelength conversion material distributed inside the first base layer.

10. The display device of claim 9, wherein the first wavelength conversion material includes a quantum dot configured to absorb blue light and convert the blue light into red light.

11. The display device of claim 1, wherein the plurality of sub-pixels include a third sub-pixel configured to emit blue light,
the plurality of optical layers include a third optical layer disposed in the third sub-pixel, and
the third optical layer includes a third base layer and a scattering material distributed inside the third base layer.

12. The display device of claim 1, wherein each of the plurality of light emitting diodes includes:
a first electrode connected with a source electrode of a thin film transistor,
a second electrode connected with a common voltage line,
an active layer configured to emit light,
a first semiconductor layer configured to provide holes to the active layer, and
a second semiconductor layer configured to provide electrons to the active layer.

13. The display device of claim 12, wherein each of the plurality of light emitting diodes has a vertical structure in which the first electrode, the first semiconductor layer, the active layer, the first semiconductor layer, and the second semiconductor layer are sequentially stacked.

14. The display device of claim 12, wherein each of the plurality of light emitting diodes has a horizontal structure in which the active layer, the first semiconductor layer, and the first electrode are stacked on one side of an upper surface of the second semiconductor layer, and the second electrode is stacked on another side of the upper surface of the second semiconductor layer.

15. The display device of claim 1, further comprising a bank disposed on the outer portion of the planarization layer,
wherein the bank is hydrophobic and includes a material that absorbs light.

16. A display device comprising:
a substrate on which a plurality of sub-pixels are disposed, each of the plurality of sub-pixels including an emitting area and a non-emitting area adjacent to the emitting area;
a plurality of light emitting diodes disposed in the emitting area on the substrate;
a planarization layer disposed on the light emitting diode; and
a plurality of optical layers disposed on the planarization layer,
wherein the planarization layer includes an opening surrounding the light emitting diode,
the planarization layer includes a central portion and an outer portion, and
the central portion is an inner area of the opening and the outer portion is an outer area of the opening.

17. The display device of claim 16, wherein the opening of the planarization layer has a ring shape centered on the light emitting diode.

18. The display device of claim 16, wherein the central portion and the outer portion of the planarization layer are spaced apart by the opening of the planarization layer.

19. The display device of claim 16, further comprising a plurality of optical layers disposed on the planarization layer,
wherein each of the plurality of optical layers covers the light emitting diode, the central portion of the planarization layer, and the opening of the planarization layer.

20. The display device of claim 19, wherein the plurality of sub-pixels include a first sub-pixel configured to emit red light, a second sub-pixel configured to emit green light, and a third sub-pixel configured to emit blue light.

21. The display device of claim 20, wherein the light emitting diode emits blue light,
the plurality of optical layers include a first optical layers disposed in the first sub-pixel, a second optical layer disposed in the second sub-pixel, and a third optical layer disposed in the third sub-pixel,
the first optical layer includes a quantum dot configured to absorb a first blue light and convert the first blue light into red light,
the second optical layer includes a quantum dot configured to absorb a second blue light and convert the second blue light into green light, and
the third optical layer includes a scattering material.

22. The display device of claim 16, further comprising a bank disposed on the outer portion of the planarization layer,
wherein the bank is hydrophobic and includes a material that absorbs light.
